(19) United States
(12) Patent Application Publication
(10) Pub. No.: US 2026/0312564 A1
(43) Pub. Date: Oct. 8, 2026

(54) MEMS RESONATOR COMPRISING IN-PHASE AND OUT-OF-PHASE ELEMENTS

(71) Applicant: KYOCERA Technologies Oy, Espoo (FI)

(72) Inventors: Eric SAGE, Espoo (FI); Aarne OJA, Espoo (FI)

(21) Appl. No.: 19/481,200

(22) PCT Filed: May 2, 2024
(86) PCT No.: PCT/FI2024/050209

§ 371 Date: Nov. 4, 2025

(30) Foreign Application Priority Data
May 4, 2023 (FI) 20235493

(51) Int. Cl. H03H 9/205; H03H 9/02; H03H 9/13; H03H 9/15

(52) U.S. Cl. CPC H03H 9/205; H03H 9/02259; H03H 9/02433; H03H 9/13; H03H 2009/02291; H03H 2009/155

(57) ABSTRACT

A MEMS, microelectromechanical systems, resonator (200) comprising an in-phase resonating element (101, 103) and an out-of-phase resonating element (102) positioned in parallel, wherein the in-phase resonating element (101, 103) and the out-of-phase resonating element (102) are mechanically connected but galvanically isolated.

### FIELD OF THE INVENTION

The present invention generally relates to microelectromechanical systems, MEMS, resonators which comprise an in-phase resonating element and an out-of-phase resonating element.

### BACKGROUND OF THE INVENTION

This section illustrates useful background information without admission of any technique described herein representative of the state of the art.

Microelectromechanical systems, MEMS, resonators are being developed to provide the same functionality as quartz resonators with benefits such as smaller chip size, reduced cost, and increased robustness against shock and vibrations.

A key performance parameter in MEMS resonators is the equivalent series resistance, ESR. ESR is inversely proportional to a quality factor Q of the resonator, and thus the minimization of ESR is often desirable. In resonators that have regions of in-phase and out-of-space motion, such as in overtone resonators, there are certain inherent challenges leading to low transduction and therefore high ESR.

### SUMMARY

It is an object of certain embodiments of the invention to reduce ESR of MEMS resonators that comprise an in-phase resonating element and an out-of-phase resonating element or at least to provide an alternative to existing technology.

According to a first example aspect of the invention there is provided a MEMS, microelectromechanical systems, resonator comprising:
an in-phase resonating element and an out-of-phase resonating element positioned adjacently (adjacent to each other), wherein
the in-phase resonating element and the out-of-phase resonating element are mechanically connected but galvanically (or electrically) isolated.

In certain embodiments, respective bottom electrodes of the in-phase resonating element and the out-of-phase resonating element are galvanically isolated (the bottom electrode of the in-phase resonating element is galvanically isolated from the bottom electrode of the out-of-phase resonating element).

In certain embodiments, a first electrical terminal provides an electrode connection (both) to a top electrode of the in-phase resonating element and to a bottom electrode of the out-of-phase resonating element.

In certain embodiments, respective bottom electrodes of the in-phase resonating element and the out-of-phase resonating element are galvanically isolated, and a first electrical terminal provides an electrode connection (both) to a top electrode of the in-phase resonating element and to a bottom electrode of the out-of-phase resonating element.

In certain embodiments, the resonator (or related apparatus) comprises only two electrical terminals or contact pads (that serve the resonator).

In certain embodiments, the in-phase resonating element and the out-of-phase resonating element are galvanically isolated by a mechanically connecting but electrically resistive region.

In certain embodiments, the electrically resistive region functions as an insulator.

In certain embodiments, both the in-phase resonating element and the out-of-phase resonating element have an ultra-heavily doped, UHD, bottom electrode of N-type.

In this context, the UHD doping refers to a doping level above 10²⁰ cm⁻³. In certain embodiments, the doping level of the in-phase resonating element and the out-of-phase resonating element is above 10¹⁹ cm⁻³.

In certain embodiments, the in-phase resonating element and the out-of-phase resonating element are mechanically connected but galvanically isolated by a substantially undoped silicon region.

In certain embodiments, the expression “substantially undoped” means an undoped region which however may comprise charge carriers (caused by diffusion) to a minor extent depending on the embodiment.

In certain embodiments, the in-phase resonating element and the out-of-phase resonating element are mechanically connected but galvanically isolated by a region of local oxidation.

In certain embodiments, the in-phase resonating element and the out-of-phase resonating element are mechanically connected but galvanically isolated by a region of SiO₂.

In certain embodiments, the in-phase resonating element and the out-of-phase resonating element are mechanically connected but galvanically isolated by a substantially undoped silicon region which has undergone oxidation. In certain embodiments, such a region presents (or comprises) SiO₂ over a defined thickness.

In certain embodiments, the in-phase resonating element and the out-of-phase resonating element are mechanically connected but galvanically isolated by a silicon region of opposing doping type creating a PN junction. For example, the resonating elements, both in phase and out of phase, are UHD doped with N-type doping but the galvanically isolating region is doped with P-type doping to create a PN junction, or vice versa.

In certain embodiments, the in-phase resonating element and the out-of-phase resonating element are UHD doped with N-and P-type doping in an alternating fashion so that the in-phase resonating element has a UHD doped bottom electrode of one type and the out-of-phase resonating element has a UHD doped bottom electrode of the other type. For example, the in-phase resonating element (or a silicon layer that forms its bottom electrode in certain embodiments) is UHD doped with N-type doping and the out-of-phase resonating element (or a silicon layer that forms its bottom electrode in certain embodiments) is UHD doped with P-type doping, or vice versa.

In certain embodiments, the in-phase resonating element and the out-of-phase resonating element are mechanically connected but galvanically isolated by a depletion region of a PN junction.

In certain embodiments, the MEMS resonator comprises a reduced or increased width or length of the in-phase resonating element or the out-of-phase resonating element to counterbalance a drive level dependency, DLD, effect.

In certain embodiments, the in-phase resonating element and the out-of-phase resonating element are mechanically connected but galvanically isolated by a silicon dioxide region.

In certain embodiments, the in-phase resonating element and the out-of-phase resonating element form an overtone resonator.

In certain embodiments, a top electrode of the in-phase resonating element is galvanically connected to a bottom electrode of the out-of-phase resonating element. Similarly, in certain embodiments, a top electrode of the out-of-phase resonating element is galvanically connected to a bottom electrode of the in-phase resonating element.

In certain embodiments, a top electrode of the in-phase resonating element is galvanically connected to a bottom electrode of the out-of-phase resonating element, and a top electrode of the out-of-phase resonating element is galvanically connected to a bottom electrode of the in-phase resonating element.

In certain embodiments, a top electrode of the in-phase resonating element is galvanically connected to a bottom electrode of the out-of-phase resonating element via a hole extending through a piezoelectric layer (or an intermediate piezoelectric layer) outside of a region of the resonating element(s). Similarly, in certain embodiments, a top electrode of the out-of-phase resonating element is galvanically connected to a bottom electrode of the in-phase resonating element via a hole extending through an intermediate piezoelectric layer outside of a region of the resonating element(s).

In certain embodiments, top electrode(s) are implemented by a layer of metal. In certain embodiments, top electrode(s) are implemented by a layer of doped silicium. In certain embodiments, bottom electrode(s) are implemented by an UHD doped silicon layer, preferably of single-crystal silicon.

In certain embodiments, the in-phase resonating element and the out-of-phase resonating element are mechanically connected throughout respective side(s) of the resonating elements.

In certain embodiments, the in-phase resonating element and the out-of-phase resonating element are mechanically connected via connection elements in a piezoelectric layer but mechanically released in the region of bottom electrodes of the in-phase and out-of-phase resonating elements.

In certain embodiments, the resonating element(s) have a material stack comprising both a layer doped with P-type doping and a layer doped with N-type doping beneath a piezoelectric layer or separated by a piezoelectric layer. In certain embodiments, the layer doped with P-type doping and the layer doped with N-type doping are layers UHD doped with P-type doping and UHD doped with N-type doping, respectively.

In certain embodiments, the in-phase resonating element and the out-of-phase resonating element are of the type stacked beam resonator where a plurality of adjacent resonating beams are connected with connection elements.

In certain embodiments, the MEMS resonator comprises a plurality of resonating elements (in-phase and/or out-of-phase), one of the resonating elements being configured to resonate in a resonance mode of a first type, and another of the resonating elements being configured to resonate in a resonance mode of another type (different from the first type).

Examples of the types of resonance modes are an in-plane length extensional (LE) mode, a width extensional (WE) mode, Lamé or square extensional (SE) modes, and a flexural mode.

In certain embodiments, the MEMS resonator comprises a plurality of resonating elements, comprising a resonating element configured to resonate in an in-phase length-extensional, LE, resonance mode and another resonating element configured to resonate in a resonance mode other than the LE mode.

In certain embodiments, the MEMS resonator comprises a plurality of resonating elements, comprising a resonating element configured to resonate in an in-phase length-extensional, LE, resonance mode and another resonating element configured to resonate in a square-extensional, SE, resonance mode.

In certain embodiments, the resonating elements are arranged to form a matrix of resonating elements.

Different non-binding example aspects and embodiments have been presented in the foregoing. The above embodiments and embodiments described later in this description are used to explain selected aspects or steps that may be utilized in implementations of the present invention. It should be appreciated that corresponding embodiments apply to other example aspects as well. Any appropriate combinations of the embodiments can be formed.

### BRIEF DESCRIPTION OF THE DRAWINGS

The invention will now be described, by way of example only, with reference to the accompanying drawings, in which:

FIG. 1a shows a schematic top view of a MEMS resonator in accordance with certain embodiments;

FIG. 1b shows a schematic top view of a MEMS resonator in accordance with certain other embodiments;

FIG. 2 shows a schematic cross-section of the resonators of FIGS. 1a and 1b;

FIGS. 3a-4b show schematic top views of further MEMS resonators in accordance with certain further embodiments;

FIG. 5a shows a schematic top view of a MEMS resonator in accordance with certain further embodiments;

FIG. 5b shows a schematic sectional view of the resonator of FIG. 5a;

FIGS. 5c-5h show further embodiments;

FIG. 6a shows a schematic top view of a MEMS resonator in accordance with yet further embodiments;

FIG. 6b shows a schematic sectional view of the resonator of FIG. 6a;

FIG. 6c shows yet further embodiments;

FIG. 7a shows a schematic top view of a MEMS resonator in accordance with yet further embodiments;

FIG. 7b shows a schematic sectional view of the resonator of FIG. 7a;

FIGS. 7c-7f show yet further embodiments;

FIGS. 8a-8b show schematic side views of resonating elements in accordance with further embodiments; and

FIG. 9 shows certain orientations of the disclosed MEMS resonators.

### DETAILED DESCRIPTION

In the following description, like numbers denote like elements.

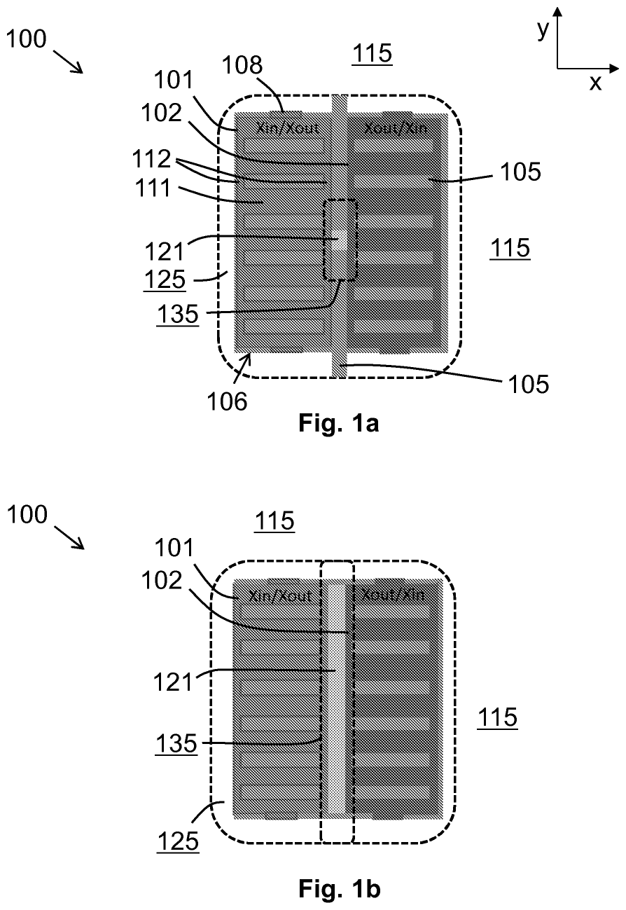

FIG. 1a shows a schematic cross-section of a MEMS resonator 100 in accordance with certain embodiments. The resonator 100 comprises an in-phase resonating element 101 and an out-of-phase resonating element 102 positioned adjacent to each other. In certain embodiments, each resonating element 101, 102 is formed of a plurality of resonating beams 111 positioned in parallel and connected by connection elements 112 at their end regions (so that each resonating element 101, 102 forms a ladder-like structure). In certain embodiments, the resonating beams 111 are positioned in parallel in a direction that is perpendicular to the direction in which the resonating elements 101, 102 are positioned in parallel.

In certain embodiments, the resonating elements 101, 102 are configured to resonate in an in-plane length extensional (LE) mode (in the length direction of the resonating beams 111). In other embodiments, a width extensional (WE) mode of a beam resonator, Lamé or square extensional (SE) modes of a square plate resonator, and/or a flexural mode of a beam resonator can be implemented. In certain embodiments, the movement of the resonating elements is actuated by piezoelectric actuation.

The in-phase resonating element 101 and the out-of-phase resonating element 102 are mechanically connected to each other by a mechanical connector 121. In other embodiments, there are more than one mechanical connector 121 connecting the in-phase resonating element 101 and the out-of-phase resonating element 102. In certain embodiments, such as in the embodiments shown in FIG. 1a, the mechanical connector 121 connects the resonating elements 101, 102 merely at a portion (preferably central portion) of the sides of the resonating elements 101, 102 facing each other. In other embodiments, such as shown in FIG. 1b, the mechanical connector 121 connects the resonating elements 101, 102 throughout respective facing side(s) of the resonating elements 101, 102.

Although the in-phase resonating element 101 and the out-of-phase resonating element 102 are mechanically connected by the mechanical connector 121, they are galvanically isolated. In certain embodiments, this is implemented so that respective bottom electrodes of the in-phase resonating element 101 and the out-of-phase resonating element 102 are galvanically isolated. In certain embodiments, the in-phase resonating element 101 and the out-of-phase resonating element 102 are galvanically isolated by a mechanically connecting but electrically resistive region as provided by the mechanical connector (connector element) 121. The electrically resistive region functions as an (electric) insulator. In the embodiments shown in FIGS. 1a and 1b, the mechanical connector 121 comprises an undoped silicon region in between the in-phase resonating element 101 and the out-of-phase resonating element 102 (or in between the bottom electrode of the of the in-phase resonating element 101 and the bottom electrode of the of the out-of-phase resonating element 102).

In certain embodiments, both the in-phase resonating element 101 and the out-of-phase resonating element 102 have an ultra-heavily doped, UHD, bottom electrode of N-type. In this context, the UHD doping refers to a doping level above 10²⁰ cm⁻³. In FIGS. 1a and 1b, reference numeral 115 depicts the P-type (resistive) substrate, and reference numeral 125 depicts the region of UHD N-type doping.

In certain embodiments, the undoped region of the mechanical connector 121 is achieved by masking an area 135 during the manufacturing phase of dopant addition. The masking area may be a bit larger than the mechanical connector 121 to take effects of diffusion into account.

In certain embodiments, the resonator 100 is separated from its surrounding (substrate 115) by appropriate trenches 105 and a cavity 106. The trenches surround the resonating structure (or resonating elements 101 and 102) of the resonator 100 and extend to the cavity underneath the resonating elements 101 and 102. Further, there are trenches 105 that separate adjacent beams 111. In certain embodiments, the resonator 100 is implemented as a suspended structure anchored to a surrounding structure by suspenders 108. In certain embodiments, the suspenders 108 are positioned at nodal points of the resonating elements 101 and 102 (at end regions of the resonating elements, preferably in the middle of the end sides of the resonating elements as shown in FIGS. 1a and 1b).

In the embodiment shown in FIG. 1a, the trenches 105 extend outside of the cavity area to separate the region of UHD N-type doping of (or over) the in-phase resonating element 101 and the region of UHD N-type doping of (or over) the out-of-phase resonating element 102.

In the embodiment shown in FIG. 1b, the masking area 135 extends outside of the cavity area to separate the region of UHD N-type doping of (or over) the in-phase resonating element 101 and the region of UHD N-type doping of (or over) the out-of-phase resonating element 102.

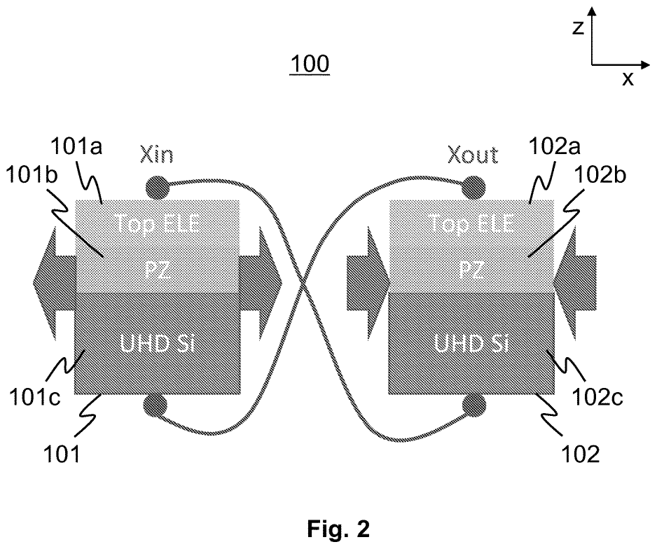

In certain embodiments, electrode connections Xin and Xout are connected as shown in FIGS. 1a and 1b. Throughout the drawings, the notation Xin/Xout means that Xin is connected to the top electrode and Xout to the bottom electrode. Accordingly, in certain embodiments, Xin is connected to the top electrode of the in-phase resonating element 101 and to the bottom electrode of the out-of-phase resonating element 102, and Xout is connected to the top electrode of the out-of-phase resonating element 102 and to the bottom electrode of the in-phase resonating element 101. These connections are further discussed in connection with FIG. 2.

In certain embodiments, the disclosed MEMS resonator 100 having the in-phase resonating element 101 and the out-of-phase resonating element 102 implements an overtone resonator.

FIG. 2 shows a schematic cross-section of the disclosed resonator 100 in accordance with certain embodiments. The in-phase resonating element 101 comprises a bottom electrode 101c, a piezoelectric layer 101b on top of the bottom electrode 101c, and a top electrode 101a on top of the piezoelectric layer 101b. Similarly, the out-of-phase resonating element 102 comprises a bottom electrode 102c, a piezoelectric layer 102b on top of the bottom electrode 102c, and a top electrode 102a on top of the piezoelectric layer 102b. The top electrodes 101a, 102a are patterned such that they electrically isolated from each other. The bottom electrodes 101c, 102c are electrically isolated by the undoped region as described in the preceding in connection with FIGS. 1a and 1b. As mentioned in the preceding, the top electrode 101a of the in-phase resonating element 101 is galvanically connected to the bottom electrode 101c of the out-of-phase resonating element 102, and the top electrode 102a of the out-of-phase resonating element 102 is galvanically connected to the bottom electrode 101c of the in-phase resonating element 101. In this way charges of same polarity can be simultaneously collected in all applicable regions of the resonator. In certain embodiments, the top electrodes 101a, 102a are implemented by a layer of metal. In certain embodiments, the bottom electrodes 101c, 102c are implemented by an N-type UHD doped silicon layer, preferably of single-crystal silicon.

In certain embodiments, the top electrodes 101a, 102a are implemented by a layer of doped silicon, preferably of single-crystal silicon.

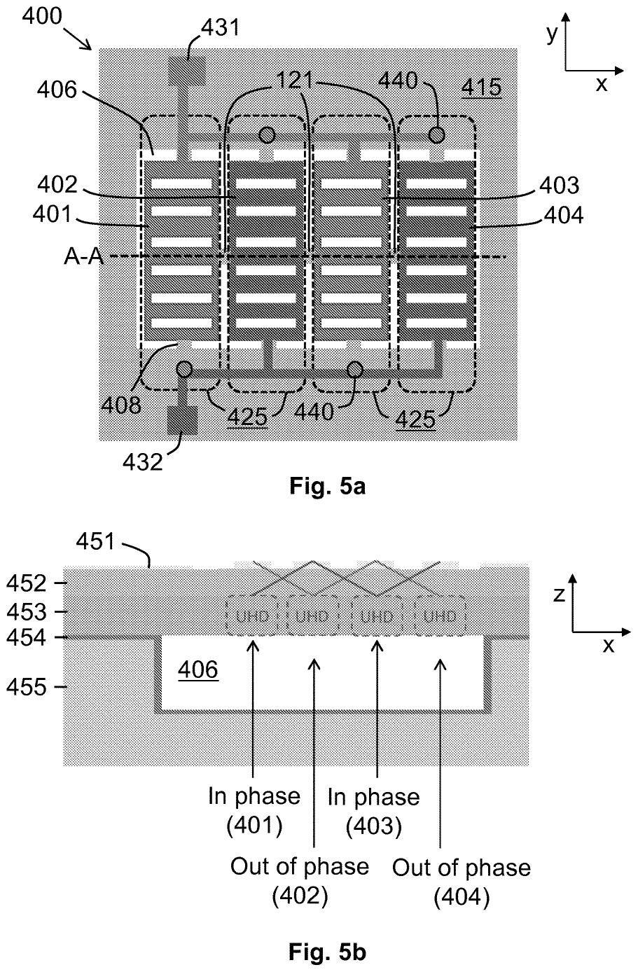

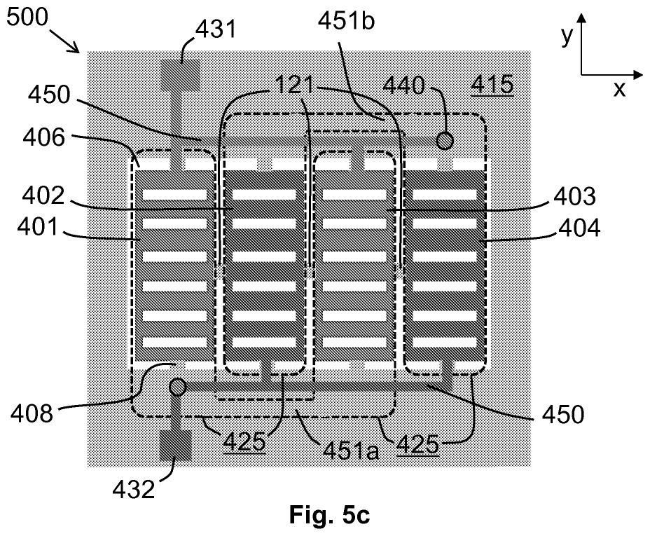

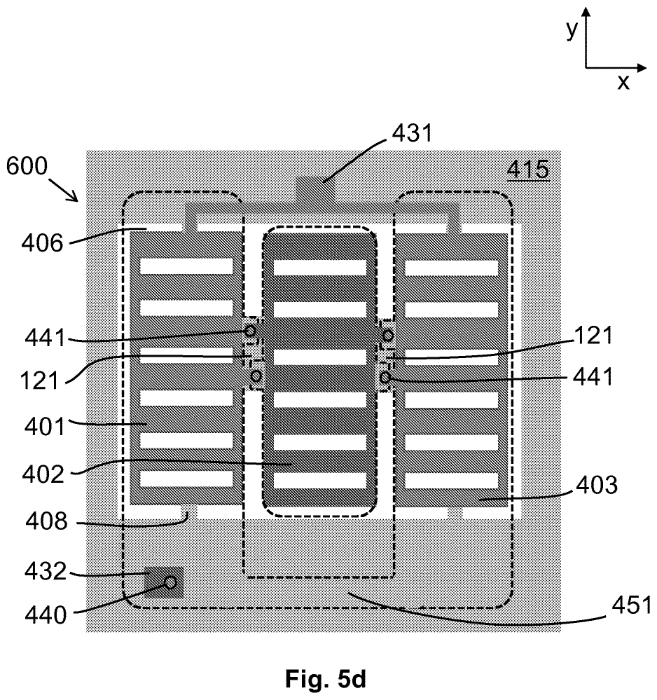

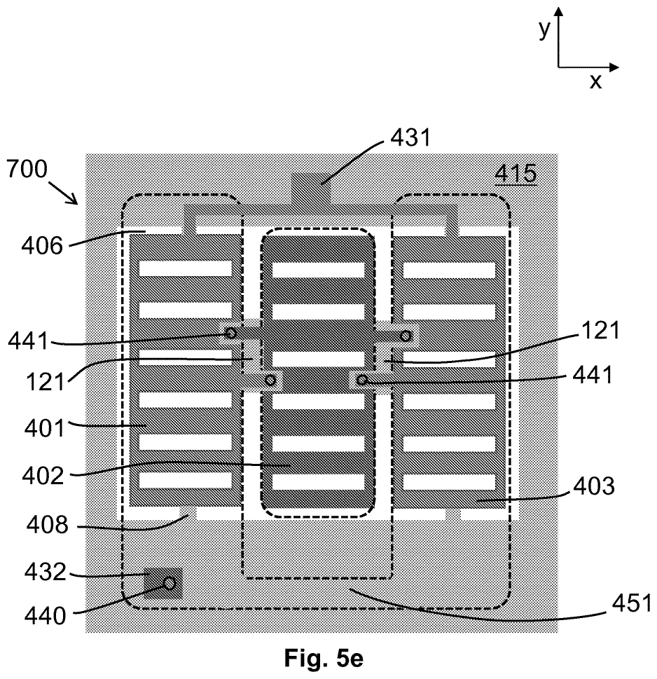

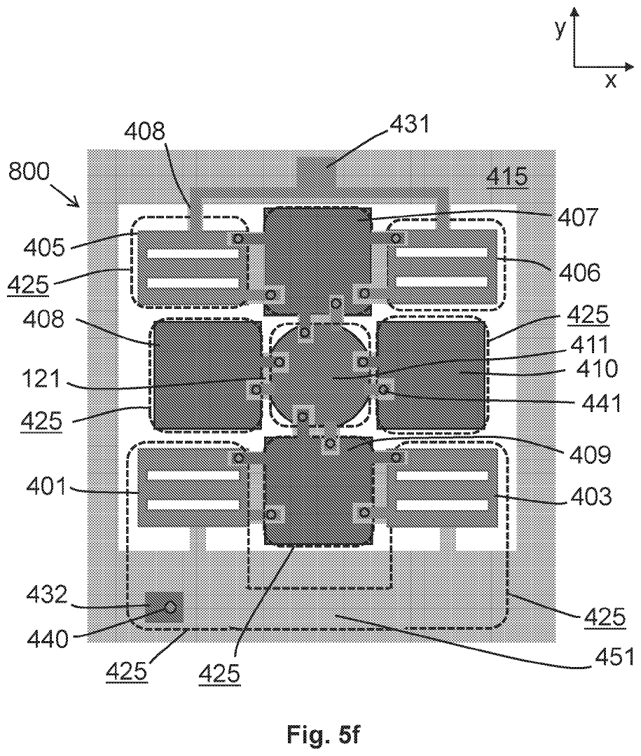

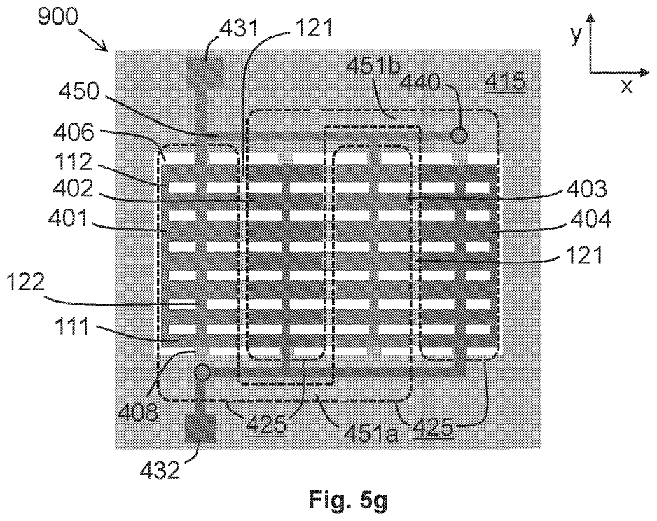

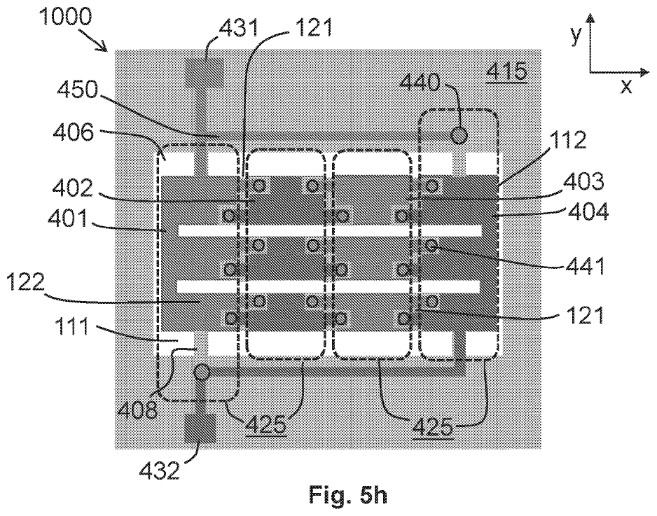

In certain embodiments, electrical connections to the bottom electrodes 101c, 102c are implemented via respective holes extending through an intermediate piezoelectric layer 101b, 102b outside of a region of the resonating elements. This will be further discussed later in connection with FIG. 5a.

In certain embodiments, electrical connections to the bottom electrodes 101c, 102c are implemented via respective holes extending through an intermediate piezoelectric layer 101b, 102b inside of a region of the resonating elements, preferably on the mechanical connector 121. This will be further discussed later e.g. in connection with FIGS. 5d and 5e.

As mentioned, the movement of the resonating elements 101, 102 is actuated by piezoelectric actuation. The arrows in FIG. 2 show that when the in-phase resonating element 101 is extending, the out-of-phase resonating element 102 is contracting.

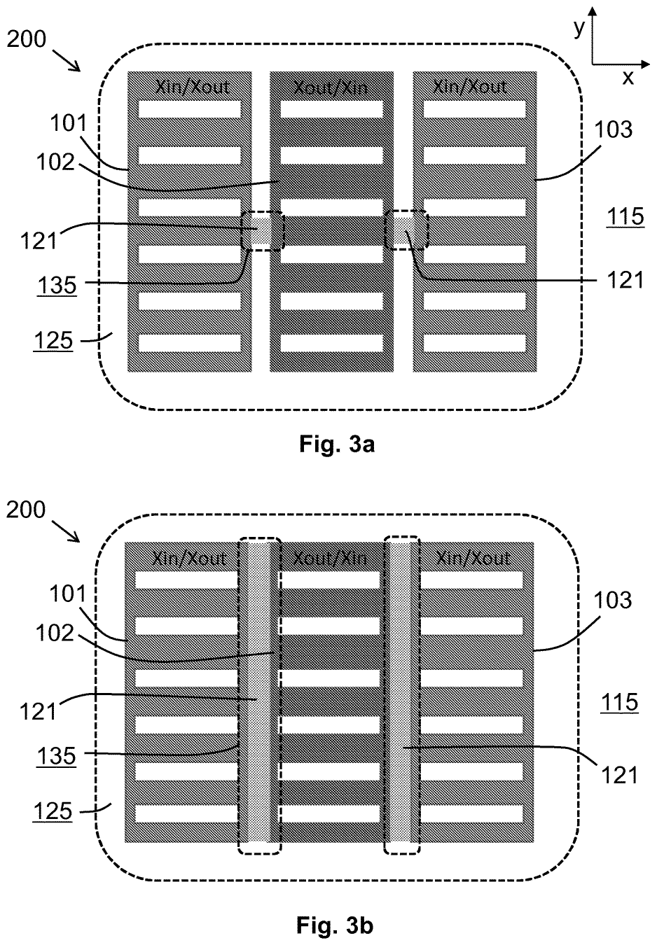

FIG. 3a shows a schematic top view of a MEMS resonator in accordance with certain further embodiments. The structural parts and operation of the MEMS resonator 200 shown in FIG. 3a otherwise corresponds to those of the MEMS resonator 100 shown in FIG. 1a except that the number of resonating elements positioned in parallel is three instead of two. The MEMS resonator 200 comprises two in-phase resonating elements 101, 103, and one out-of-phase resonating element 102 positioned in between the two in-phase resonating elements 101, 103. The resonating elements are mechanically connected but galvanically isolated by similar mechanical connectors 121 as explained in connection with FIG. 1a. Similarly, the top electrodes of the in-phase resonating elements 101, 103 are connected to the bottom electrode of the out-of-phase resonating element 102, and the top electrode of the out-of-phase resonating element 102 is connected to the bottom electrodes of the in-phase resonating elements 101, 103.

FIG. 3b shows a schematic top view of a MEMS resonator in accordance with certain further embodiments. The MEMS resonator 200 of FIG. 3b otherwise completely corresponds to the MEMS resonator 200 of FIG. 3a except that in the resonator 200 of FIG. 3b the mechanical connectors 121 connect the resonating elements 101-103 throughout respective facing side(s) of the resonating elements 101-103.

In certain embodiments, the in-phase resonating element and the out-of-phase resonating element are UHD doped with N-and P-type doping in an alternating fashion so that the in-phase resonating element has a UHD doped bottom electrode of one type and the out-of-phase resonating element has a UHD doped bottom electrode of the other type. For example, the in-phase resonating element (or a silicon layer that forms its bottom electrode in certain embodiments) is UHD doped with N-type doping and the out-of-phase resonating element (or a silicon layer that forms its bottom electrode in certain embodiments) is UHD doped with P-type doping, or vice versa. In other embodiments the P-type doping is HD (highly doped). In this context, the HD doping refers to a doping level between 10¹⁸ cm⁻³ and 10²⁰ cm⁻³.

In certain such embodiments, the in-phase resonating element and the out-of-phase resonating element are mechanically connected but galvanically isolated by a depletion region of a PN junction.

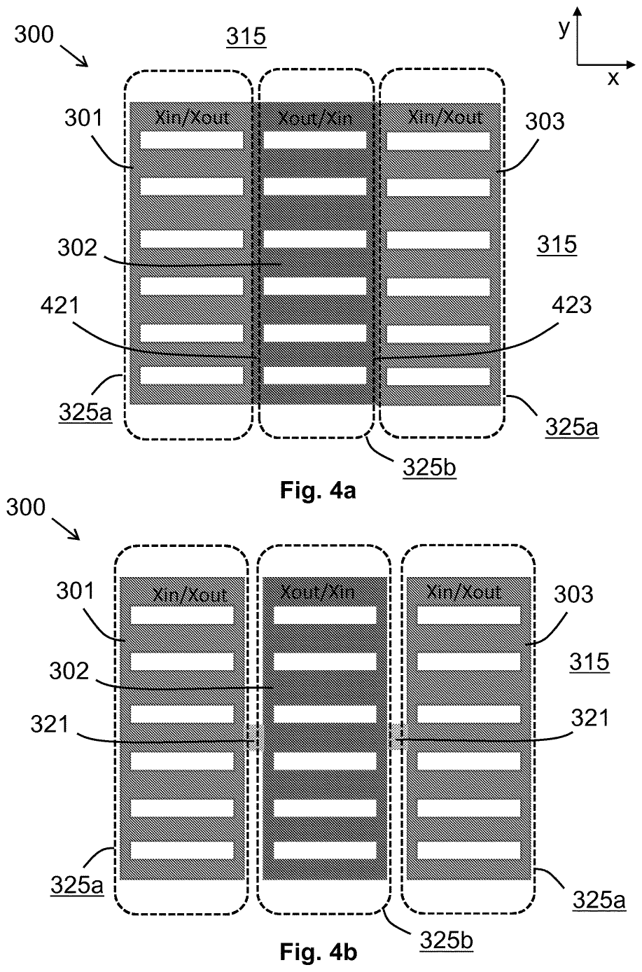

An example of such a MEMS resonator 300 having resonating elements with alternating N-and P-type doping is shown in FIG. 4a. The resonator 300 comprises a first in-phase resonating element 301, an out-of-phase resonating element 302, and a second in-phase resonating element 303 positioned in parallel side by side. In certain embodiments, each resonating element 301-303 is formed of a plurality of resonating beams positioned in parallel and connected by connection elements at their end regions (so that each resonating element 301-303 forms a ladder-like structure). In certain embodiments, the resonating beams are positioned in parallel in a direction that is perpendicular to the direction in which the resonating elements 301-303 are positioned in parallel.

In certain embodiments, the resonating elements 301-303 are configured to resonate in an in-plane length extensional mode (in the length direction of the resonating beams). In certain embodiments, the movement of the resonating elements is actuated by piezoelectric actuation.

Adjacent resonating elements 301 and 302 as well as 302 and 303 are in a mechanical contact with each other throughout respective sides of the resonating elements, although in other embodiments, such as in the embodiments shown in FIG. 4b, a respective mechanical connector 321 connects the resonating elements 301 and 302 (302 and 303, respectively) merely at a portion (preferably central portion) of the sides of the respective resonating elements 301-303 facing each other.

Although the first in-phase resonating element 301 and the out-of-phase resonating element 302 are mechanically connected, they are galvanically isolated. In certain embodiments, this is implemented so that respective bottom electrodes of the first in-phase resonating element 301 and the out-of-phase resonating element 302 are galvanically isolated. In certain embodiments, the first in-phase resonating element 301 (or its bottom electrode) is UHD doped with N-type doping and the out-of-phase resonating element 302 (or its bottom electrode) is UHD or HD doped with P-type doping. Galvanic isolation of these elements 301 and 302 (or their bottom electrodes) is obtained by a depletion region of a PN junction 421 forming at an interface between the first in-phase resonating element 301 and the out-of-phase resonating element 302. Similarly, although the second in-phase resonating element 303 and the out-of-phase resonating element 302 are mechanically connected, they are galvanically isolated. In certain embodiments, this is implemented so that respective bottom electrodes of the second in-phase resonating element 303 and the out-of-phase resonating element 302 are galvanically isolated. In certain embodiments, the second in-phase resonating element 303 (or its bottom electrode) is UHD doped with N-type doping. The out-of-phase resonating element 302 (or its bottom electrode) is UHD or HD doped with P-type doping. Galvanic isolation of these elements 302 and 303 (or their bottom electrodes) is obtained by a depletion region of a PN junction 423 forming at an interface between the second in-phase resonating element 303 and the out-of-phase resonating element 302.

Similar depletion regions of a PN junction may be arranged at interfaces of all adjacent resonating elements in the event the resonator 300 includes further resonating elements.

In this context, again, the UHD doping refers to a doping level above 10²⁰ cm⁻³. In FIGS. 4a and 4b, reference numeral 315 depicts a (resistive) substrate which may be of P-type or N-type. The reference numeral 325a depicts the region of UHD N-type doping of the in-phase resonating elements 301, 303, and the reference numeral 325b depicts the region of UHD P-type doping of the out-of-phase resonating element 302.

In certain embodiments, the resonator 300 is separated from its surrounding (substrate 315) by appropriate trenches and a cavity (not shown in FIGS. 4a and 4b, but may be similarly implemented as explained in connection of FIGS. 1a and 1b). The trenches surround the resonating structure (or resonating elements 301-303) of the resonator 300 and extend to the cavity underneath the resonating elements 301-303. In certain embodiments, the resonator 300 is implemented as a suspended structure anchored to a surrounding structure by suspenders (not shown in FIGS. 4a and 4b, but may be similarly implemented as explained in connection of FIGS. 1a and 1b). In certain embodiments, the suspenders are positioned at nodal points of the resonating elements 301-303 (at end regions of the resonating elements, preferably in the middle of the end sides of the resonating elements similarly as shown in FIGS. 1a and 1b).

In certain embodiments, electrode connections Xin and Xout are connected as shown in FIGS. 4a and 4b. Accordingly, in certain embodiments, Xin is connected to the top electrodes of the in-phase resonating elements 301 and 303, and to the bottom electrode of the out-of-phase resonating element 302, and Xout is connected to the top electrode of the out-of-phase resonating element 302 and to the bottom electrodes of the in-phase resonating elements 301 and 303.

The disclosed MEMS resonator 300 operates well e.g. as an overtone resonator.

FIG. 5a shows a schematic top view of a MEMS resonator 400 of the type shown in FIG. 1a and FIG. 5b a schematic sectional view of the resonator 400 (along the section A-A marked in FIG. 5a). The resonator 400 comprises four adjacently positioned resonating elements 401-404 (preferably positioned in parallel). In-phase and out-of-phase resonating elements alternate in the layout such that the first and third resonating element 401 and 403 are in-phase resonating elements, and the second and fourth resonating element 402 and 404 are out-of-phase resonating elements. In certain embodiments, each resonating element 401-404 is formed of a plurality of resonating beams positioned in parallel and connected by connection elements at their end regions (so that each resonating element 401-404 forms a ladder-like structure). In certain embodiments, the resonating beams are positioned in parallel in a direction that is perpendicular to the direction in which the resonating elements 401-404 are positioned in parallel.

In certain embodiments, the resonating elements 401-404 are configured to resonate in an in-plane length extensional mode (in the length direction of the resonating beams, i.e. in the direction of x-axis). In certain embodiments, the movement of the resonating elements is actuated by piezoelectric actuation.

An in-phase resonating element 401, 403 is mechanically connected to an adjacent out-of-phase resonating element 402, 404 by a mechanical connector 121 positioned in between the resonating elements concerned. In certain embodiments, such as in the embodiments shown in FIGS. 5a and 5b, a respective mechanical connector 121 connects adjacent resonating elements merely at a portion (preferably central portion) of the sides of the resonating elements facing each other (the adjacent resonating element may be otherwise isolated by isolation trenches). In other embodiments, the mechanical connector 121 connects the resonating elements throughout respective facing side(s) of the resonating elements.

Although the in-phase resonating elements 401, 403 and the out-of-phase resonating elements 402, 404 are mechanically connected by respective mechanical connectors 121, they are galvanically isolated. In certain embodiments, this is implemented so that respective bottom electrodes of the in-phase resonating elements 401, 403 and the out-of-phase resonating elements 402, 404 are galvanically isolated. In certain embodiments, the in-phase resonating elements 401, 403 and the out-of-phase resonating elements 402, 404 are galvanically isolated by a mechanically connecting but electrically resistive region as provided by the mechanical connector (connector element) 121. The electrically resistive region functions as an (electric) insulator. In the embodiments shown in FIGS. 5a and 5b, each mechanical connector 121 comprises an undoped silicon region in between a respective in-phase resonating element 401, 403 and a respective out-of-phase resonating element 402, 404 (or in between the bottom electrodes of the of the in-phase and out-of-phase resonating elements concerned).

In the embodiments shown in FIGS. 5a and 5b (like in other embodiments), bottom electrodes of each in-phase and out-of-phase resonating element may be implemented by an ultra-heavily doped, UHD, local doping of a single crystal silicon layer.

Accordingly, in certain embodiments, both the in-phase resonating elements 401, 403 and the out-of-phase resonating elements 402, 404 have an ultra-heavily doped, UHD, bottom electrode of N-type. In this context, again, the UHD doping refers to a doping level above 10²⁰ cm⁻³. In FIG. 5a, reference numeral 415 depicts the P-type (resistive) substrate, and reference numeral 425 depicts the region of UHD N-type (local) doping. It should be noted that the reference numeral 415 may refer, in the embodiment shown in FIG. 5a and in other embodiments, alternatively to a highly resistive device layer of a substrate wafer (such as the device (or bottom electrode) layer 453 later described in connection with FIG. 5b).

In certain embodiments, the undoped region of the mechanical connector 121 is achieved by masking the area (as shown in preceding embodiments) of each connector element 121 during the manufacturing phase of dopant addition. The masking area may be a bit larger than the mechanical connector 121 to take effects of diffusion into account.

In certain embodiments, the resonator 400 is separated from its surrounding (substrate 415) by appropriate trenches and a cavity 406. The trenches surround the resonating structure (or resonating elements 401-404) of the resonator 400 and extend to the cavity 406 underneath the resonating elements 401-404. In certain embodiments, the resonator 400 is implemented as a suspended structure anchored to a surrounding structure by suspenders 408. In certain embodiments, the suspenders 408 are positioned at nodal points of the resonating elements 401-404 (at end regions of the resonating elements, preferably in the middle of the end sides of the resonating elements).

FIG. 5a further shows a first electrical terminal 431 providing an electrode connection Xin to top electrodes of the in-phase resonating elements and to bottom electrodes of the out-of-phase resonating elements. Further, a second electrical terminal 432 provides an electrode connection Xout to top electrodes of the out-of-phase resonating elements and to bottom electrodes of the in-phase resonating elements.

In certain embodiments, as depicted in FIG. 5a, the top electrodes of the in-phase resonating elements are galvanically connected to bottom electrodes of the out-of-phase resonating elements via respective (e.g., vertical) holes 440 extending through an intermediate piezoelectric layer outside of a region of the resonating element(s).

Different layers of the MEMS resonator 400 are visible in the schematic sectional view of FIG. 5b. In-phase and out-of-phase motion regions alternate in the structure. Each of the resonating elements 401-404 comprises a (preferably metallic) top electrode (the top electrode layer is depicted by reference numeral 451 in FIG. 5b). Electrical isolation of the top electrodes between the top electrode(s) of the in-phase resonating element(s) and out-of-phase resonating element(s) is implemented e.g. by patterning. A piezoelectric layer (e.g. an AlN layer) 452 resides beneath the top electrode layer 452. In the example shown in FIG. 5b, the piezoelectric layer 452 is common for each resonating element. A bottom electrode layer (device layer) 453 resides beneath the piezoelectric layer 452. As mentioned, bottom electrodes of each resonating element are implemented in certain embodiments by a local doping of UHD N-type (in the bottom electrode layer 453 of single crystal silicon). The local dopings are separated by undoped regions (of the highly resistive device layer 453) as mentioned in the preceding. In certain embodiments, there is an electrically insulation layer (e.g. of SiO₂) 454 beneath the bottom electrode layer 453. The resonating elements are separated from the P-type (highly resistive) substrate 455 by the cavity 406. The used substrate may be e.g. a P-type SOI wafer or similar.

The electrode connection Xin provided by the first terminal 431 connects the top electrodes of the in-phase resonating elements and the bottom electrodes of the out-of-phase resonating elements. The electrode connection Xout provided by the second terminal 432 connects the top electrodes of the out-of-phase resonating elements and the bottom electrodes of the in-phase resonating elements. These connections are schematically shown in FIG. 5b.

In certain embodiments, as shown in the MEMS resonator 500 of FIG. 5c, the electrical connections of the bottom electrodes of in-phase resonating elements 401 and 403 are implemented through an N-type UHD channel 451a (outside of a region of the resonating elements). Similarly, the electrical connections of the bottom electrodes of out-of-phase resonating elements 402 and 404 are implemented through another N-type UHD channel 451b (outside of a region of the resonating elements). This patterning of UHD doping enables the reduction of required holes 440 extending through an intermediate piezoelectric layer as well as the reduction of static capacitance.

In certain embodiments, the holes extending through an intermediate piezoelectric layer are positioned inside the resonator area. In the MEMS resonator 600 shown in FIG. 5d, the mechanical connector 121 between adjacent resonating elements includes a region where the UHD doping of a nearby resonating element 401 and 402 extends. The holes (herein denoted as holes 441) are placed in the UHD doped region of the mechanical connector 121. A top electrode trace of an adjacent resonating element is arranged to overlap with the holes 441 to create the interconnection. In effect, the top electrode of the in-phase resonating element 401 has a trace connected to the hole 441 which is placed on the mechanical connector 121 and within the UHD region of the out-of-phase resonating element 402 thereby electrically connecting the top electrode of the in-phase resonating element 401 with the bottom electrode of the out-of-phase resonating element 402. Similarly, the top electrode of the out-of-phase resonating element 402 has a trace connected to the hole 441 which is placed on the mechanical connector 121 and within the UHD region of in-phase resonating element 401 thereby electrically connecting the top electrode of the out-of-phase resonating element 402 with the bottom electrode of the in-phase resonating element 401. In this configuration, some resonating elements, such as the out-of-phase resonating element 402, do not need an anchor point 408.

The electrode connection Xin provided by the first terminal 431 connects the top electrodes of the in-phase resonating elements and the bottom electrodes of the out-of-phase resonating elements via the holes 441. The electrode connection Xout provided by the second terminal 432 connects the bottom electrodes of the in-phase resonating elements and the top electrodes of the out-of-phase resonating elements via the holes 441. Xout is galvanically connected to bottom electrodes of the in-phase resonating elements via respective (e.g., vertical) holes 440 extending through an intermediate piezoelectric layer outside of a region of the resonating element(s).

In certain embodiments, as in the MEMS resonator 700 shown in FIG. 5e, the holes 441 are placed directly on the resonating elements 401, 402 and 403. A gap is patterned in the top electrode layer around each hole to ensure galvanic isolation between the hole and the top electrode of the resonating element it is present in. A (metal) trace from a resonating element of opposing phase is extended to reach the hole and ensure an electrical connection between the top electrode and the bottom electrode of the resonating element of opposing phase. In effect, the hole 441 present in the in-phase resonating element 401 is electrically isolated from the top electrode of the in-phase resonating element 401 by patterning a gap around it and is connected to the top electrode of the out-of-phase resonating element 402 via an extended (metal) trace. In this configuration some resonating elements such as 402 do not need an anchor point 408.

In certain embodiments, as shown in FIG. 5f, the MEMS resonator 800 is composed of resonating elements which can be of a different type than length extensional (LE) mode resonators. In-phase resonating elements 401, 403, 405 and 406 are length extensional while out-of-phase resonating element 407, 408 and 409, 410 are configured to resonate in a square extensional (SE) resonance mode. The in-phase resonator 411 is a disk resonator. As shown in FIG. 5f, the use of 2D bulk resonators such as disk and square extensional resonators enables the design of a matrix of resonating elements rather than an array or arrays. Other types of bulk mode resonators not present in FIG. 5f may include e.g. a ring resonator.

In certain embodiments, as shown in FIG. 5g, the MEMS resonator 900 is formed of a plurality of resonating beams 111 positioned in parallel and connected by connection elements 112 at their end regions. Each beam resonates at an overtone, here overtone 4, and top electrodes are patterned to galvanically isolate regions of opposite phase i.e. regions of compression and extension. The bottom electrodes are patterned using UHD masking to galvanically isolate regions of opposite phase i.e. regions of compression and extension. The UHD masked regions are the mechanical connectors 121 as described in previous embodiments. In this embodiment all beams 111 have a common connection through a holder 122 perpendicular to the beams length and placed at their nodal points. The holder 122 allows an electrical interconnection between all beams 111 for both the bottom and top electrode and for in-phase regions and out-of-phase regions separately.

In other embodiments, as shown in FIG. 5h, the use of a holder 122 as seen for a MEMS resonator 1000 is avoided by using holes 441 on the resonator area. The resonator 1000 is formed of a plurality of resonating beams 111 positioned in parallel and connected by connection elements 112 at their end regions. Each beam resonates at an overtone, here overtone 4, and top electrodes are patterned to galvanically isolate regions of opposite phase i.e. regions of compression and extension. The bottom electrodes are patterned using UHD masking to galvanically isolate regions of opposite phase i.e. regions of compression and extension. The UHD masked regions are the mechanical connectors 121 as described in previous embodiments. Electrical interconnections are implemented as described in the embodiments of FIG. 5e and FIG. 5f.

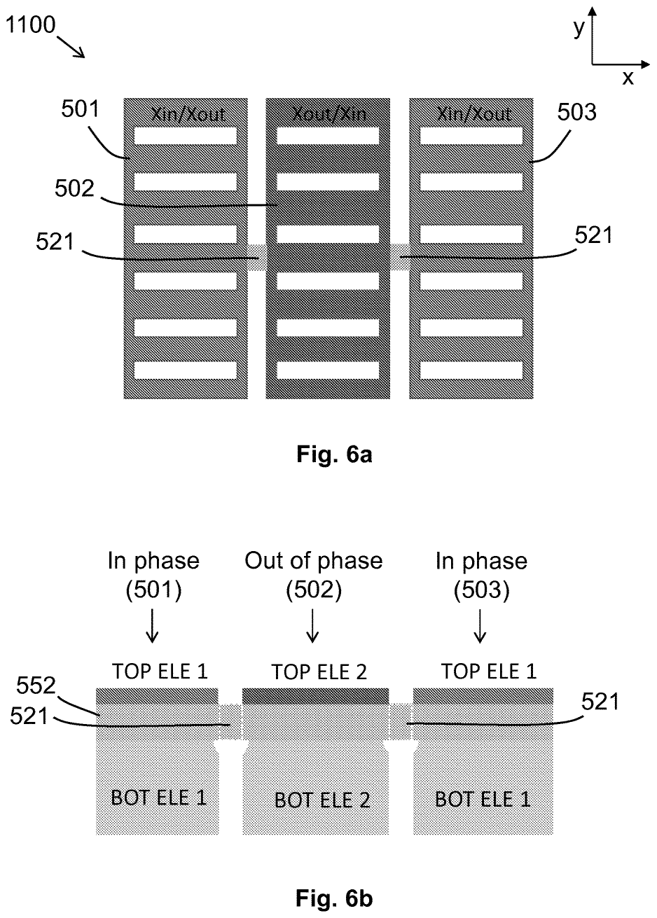

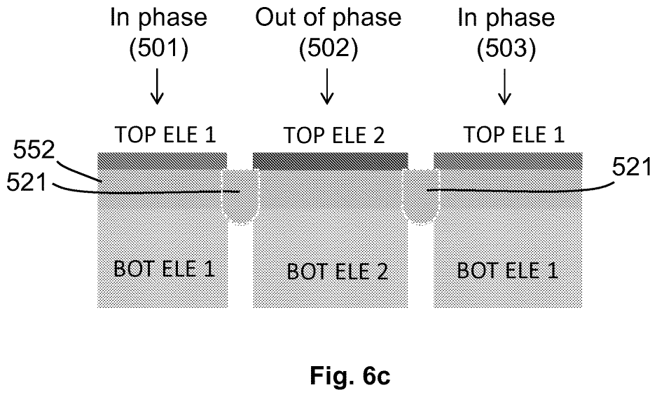

FIG. 6a shows a schematic top view of a MEMS resonator 1100 and FIG. 6b a schematic sectional view of the resonator 1100 (along the section B-B marked in FIG. 6a). The resonator 1100 comprises a first in-phase resonating element 501, an out-of-phase resonating element 502, and a second in-phase resonating element 503 positioned in parallel side by side. In certain embodiments, each resonating element 501-503 is formed of a plurality of resonating beams positioned in parallel and connected by connection elements at their end regions (so that each resonating element 501-503 forms a ladder-like structure). In certain embodiments, the resonating beams are positioned in parallel in a direction that is perpendicular to the direction in which the resonating elements 501-503 are positioned in parallel.

In certain embodiments, the resonating elements 501-503 are configured to resonate in an in-plane length extensional mode (in the length direction of the resonating beams). In certain embodiments, the movement of the resonating elements is actuated by piezoelectric actuation.

Adjacent resonating elements are in a mechanical contact with each other via respective facing sides of the resonating elements so that a mechanical connector 521 connects the resonating elements at a portion (preferably central portion) of the sides of the respective resonating elements 501-503 facing each other. However, as shown in FIG. 6b, the mechanical connectors 521 herein are mere piezoelectric layer connection elements. The in-phase resonating elements 501, 503 and the out-of-phase resonating element 502 are mechanically connected via connection elements (mechanical connectors) 521 in the piezoelectric layer 552 but mechanically released from each other in the bottom electrode layer. Silicon (in the bottom electrode layer) below the piezoelectric layer mechanical connectors 521 may be etched away by making release holes in the piezoelectric layer and by using e.g. a slightly isotropic DRIE etch chemistry for silicon (or Xe etch). Doping of the (silicon) bottom electrode layer (device layer) may be laterally uniform (e.g., N-type doping).

Electrode connections Xin and Xout are connected such that Xin is connected to the top electrodes (TOP ELE 1) of the in-phase resonating elements 501 and 503, and to the bottom electrode (BOT ELE 2) of the out-of-phase resonating element 502, and Xout is connected to the top electrode (TOP ELE 2) of the out-of-phase resonating element 502 and to the bottom electrodes (BOT ELE 1) of the in-phase resonating elements 501 and 503.

Otherwise, the structure and operation of the MEMS resonator 1100 generally corresponds to the structure and operation of MEMS as described hereinbefore.

FIG. 6c shows a variation of the MEMS resonator 1100 having trenches etched first and only the depositing the piezoelectric layer 552. This will lead into the formation of the mechanical connectors 521 in the shape shown in FIG. 6c.

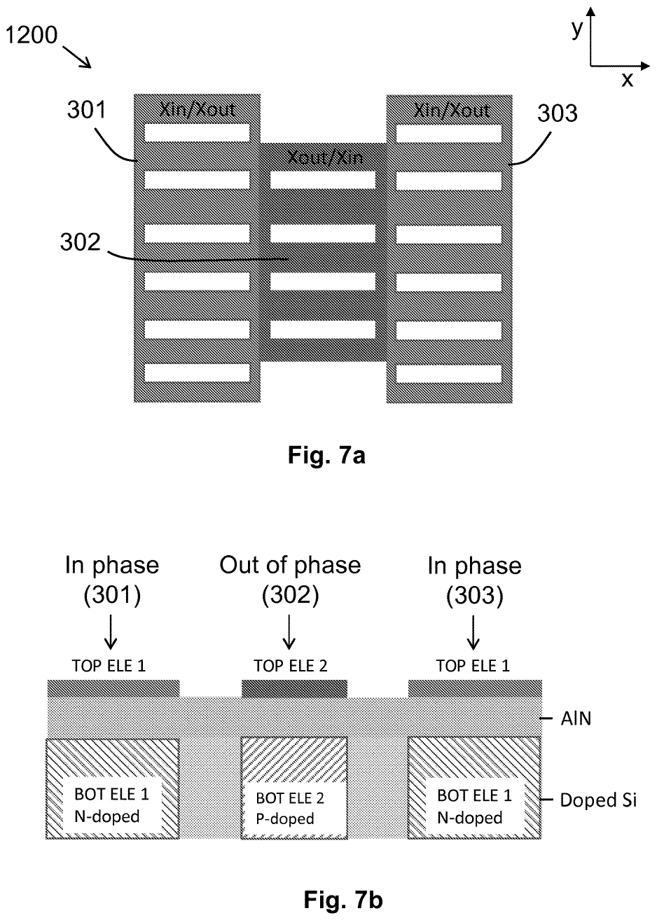

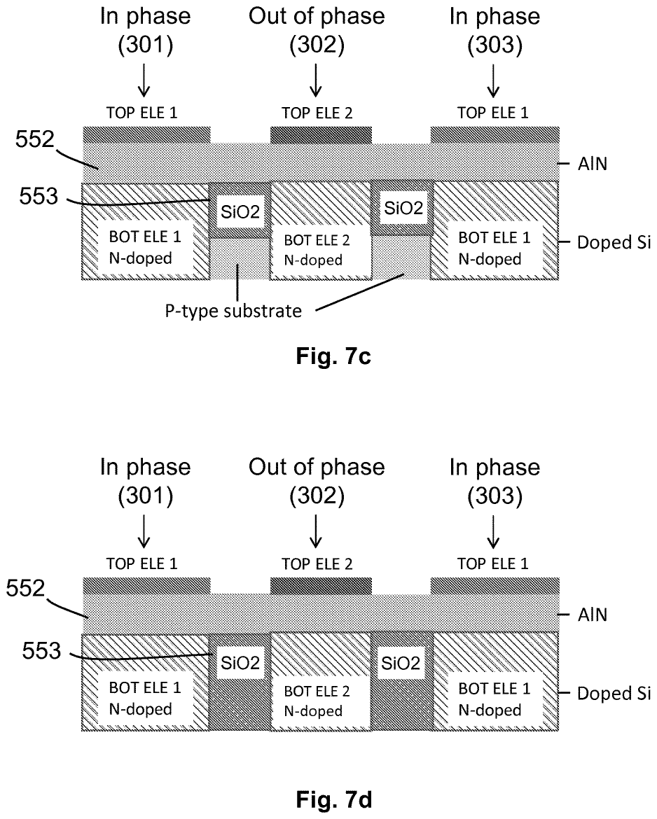

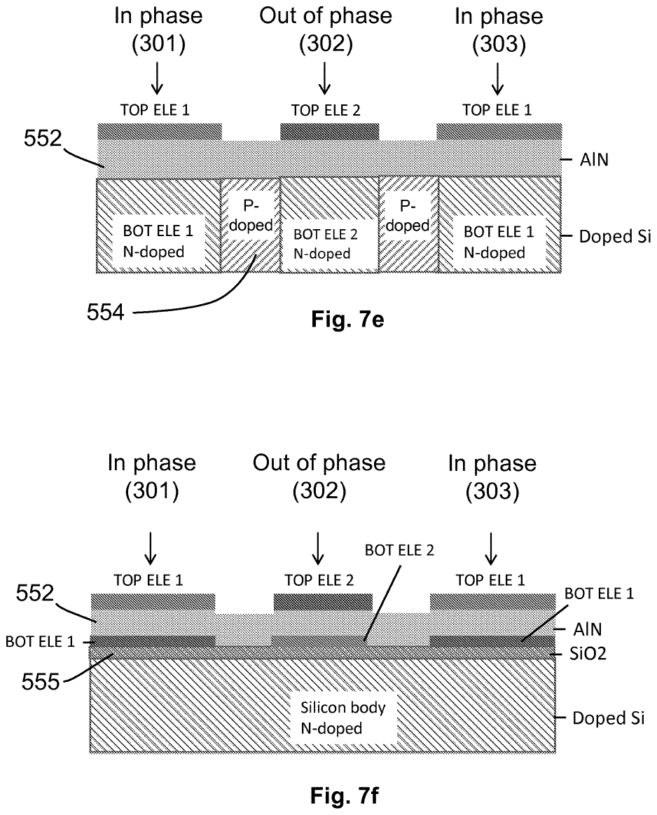

FIG. 7a shows a schematic top view of a MEMS resonator 1200 and FIG. 7b a schematic sectional view of a resonator of the type of resonator 1200 of FIG. 7a. The resonator 1200 corresponds to the resonator 300 shown in FIG. 4a in structure and operation except that the out-of-phase resonating element 302 deviates from the one shown in FIG. 4a. In certain embodiments, the out-of-phase resonating element 302 has a reduced length (or dimension in the direction of y-axis) in comparison to the length of the in-phase resonating elements 301, 303 in order to counterbalance a drive level dependency, DLD, effect. In other embodiments, as shown in FIG. 7b, the out-of-phase resonating element 302 has a reduced width in comparison to the width of the in-phase resonating elements 301, 303 in order to counterbalance a drive level dependency, DLD, effect. In other embodiments, the out-of-phase resonating element 302 has an increased length or width in comparison to the length or width of the in-phase resonating elements 301, 303.

The required sizing of the out-of-phase resonating element as to counterbalance the DLD effect depends on each particular embodiment. In certain embodiments, the top electrode of the out-of-phase resonating element 302 is omitted to simplify the resonator structure.

The DLD counterbalancing in practice comprises balancing non-linear material softening or hardening effects by suitable dimensioning. Material spring hardening effects of N-type doping region(s) are balanced with material spring softening effects of P-type doping region(s).

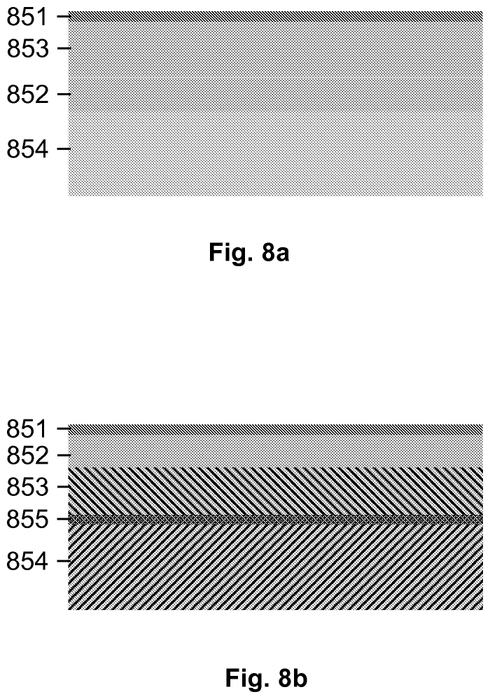

FIG. 8a shows a schematic side view of a resonating element (either in-phase or out-of-phase) applicable to the presented embodiments. The side view depicts a material stack comprising a thin (top electrode) metal layer on top, a doped first single crystal silicon layer (or region) 853 (either P-doped or N-doped) beneath the metal layer 851, an AlN layer (piezoelectric layer) 852 beneath the doped first single crystal silicon layer 853, and a doped second single crystal silicon layer (or region) 854 (N-doped or P-doped, respectively) beneath the piezoelectric layer 852.

DLD effects are counterbalanced close to zero by choosing an optimal ratio for the thicknesses of the single-crystalline P-doped and N-doped layers depending on the embodiment. Thickness of the P-doped and N-doped layers is selected depending on the strength of the DLD effects for N-doped and P-doped silicon. If, for example, DLD effects for P-doped silicon are stronger, a thinner P-doped layer is sufficient for counterbalancing the DLD effects of a thicker N-doped layer.

FIG. 8b shows a further schematic side view of a resonating element (either in-phase or out-of-phase) applicable to the presented embodiments. The side view depicts a material stack comprising a thin (top electrode) metal layer 851 on top, an AlN layer (piezoelectric layer) 852 beneath the metal layer 851, a doped first single crystal silicon layer (or region) 853 (either P-doped or N-doped) beneath the piezoelectric layer 852, and a doped second single crystal silicon layer (or region) 854 (N-doped or P-doped, respectively) beneath the doped first single crystal silicon layer 853. The material stack further comprises a compensated region 855 (with poor electrical conductivity, e.g. a single crystal silicon region) between the doped first and second single crystal silicon layers 853, 854.

DLD effects are counterbalanced close to zero by choosing an optimal ratio for the thicknesses of the single-crystalline P-doped and N-doped layers depending on the embodiment. Thickness of the P-doped and N-doped layers is selected depending on the strength of the DLD effects for N-doped and P-doped silicon. If, for example, DLD effects for P-doped silicon are stronger, a thinner P-doped layer is sufficient for counterbalancing the DLD effects of a thicker N-doped layer.

In further embodiments, as shown in FIG. 7c, a local oxidation of the mechanical connector creates a SiO₂ layer 553 below the piezoelectric layer 552. In yet further embodiments, as shown in FIG. 7d, a trench is filled with silicon dioxide to enable the SiO₂ layer 553 to extend to the cavity. In yet further embodiments, as shown in FIG. 7e, in-phase resonating elements 301 and 303 as well as the out-of-phase resonating element 302 have bottom electrodes of the same doping type, preferably N-type UHD, and are galvanically isolated though the doping of opposite type in the region 554 of the mechanical connector to create a PN junction and generate galvanic isolation between bottom electrodes of in-phase resonating elements 301, 303 and the out-of-phase element 302.

In yet further embodiments, as shown in FIG. 7f, in-phase resonating elements 301 and 303 as well as the out-of-phase resonating element 302 have a silicon body of the same doping type, preferably N-type UHD. A galvanic isolation layer 555, preferably SiO₂, is deposited on top of the silicon body. Metallic bottom electrodes are deposited and patterned for each resonating element 301, 302 and 303 on top of the isolation layer 555. The top electrodes of the resonating elements 301 and 303 are electrically connected to the bottom electrode of the resonating element 302 while the top electrode of the resonating element 302 is electrically connected to the bottom electrodes of the resonating elements 301 and 303.

Preferably, one of the <100> crystal orientations, most preferably [100], is along the direction of the vibrations of the length extensional resonance mode. This applies to all embodiments.

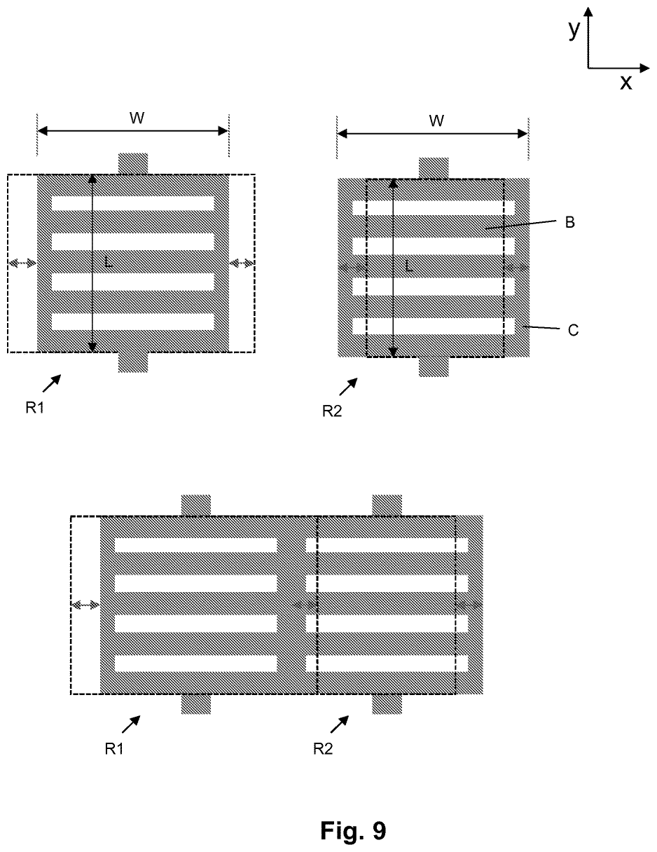

FIG. 9 yet finally shows certain defined orientations of the preceding MEMS resonators. Only beam resonators are discussed. However, the principles of orientation defined herein may also be applied to other embodiments. A resonating element is formed of resonating beams B connected with connector elements C. The length L of the resonating element depends on how many beams are placed in parallel. The length L is measured in the direction of y-axis, since this is typically the direction in which the resonator element in longer. The width W of the resonating element is measured in the direction of the x-axis. In certain embodiments, the width W equals the length of each individual resonating beam B.

FIG. 9 shows two resonating elements, R1 and R2. The resonating element R1 is in its extended shape and the resonating element R2 in its compressed shape. Each beam B resonates in the direction of the x-axis (in the length direction of the beam), i.e. in the width direction of the resonating element. Displacement from a rest position is denoted by the arrows. The lower drawing of FIG. 9 shows the in-phase and out-of-phase motion of the LE resonance mode. Accordingly, when one resonator (here: R1) is in its extended shape, the other (R2) is in its compressed shape.

Without limiting the scope and interpretation of the patent claims, certain technical effects of one or more of the example embodiments disclosed herein are listed in the following. A technical effect is reduction of ESR in MEMS resonators that comprise an in-phase resonating element and an out-of-phase resonating element through the use of local doping. A further technical effect is efficient electrical isolation of in-phase and out-of-phase regions in a silicon bottom electrode layer. A further technical effect is counterbalance of a drive level dependency effect.

It should be noted that the terms “in-phase” and “out-of-phase” are interchangeable in the presented embodiments.

The foregoing description has provided by way of non-limiting examples of particular implementations and embodiments of the invention a full and informative description of the best mode presently contemplated by the inventors for carrying out the invention. It is however clear to a person skilled in the art that the invention is not restricted to details of the embodiments presented above, but that it can be implemented in other embodiments using equivalent means without deviating from the characteristics of the invention.

Furthermore, some of the features of the above-disclosed embodiments of this invention may be used to advantage without the corresponding use of other features. As such, the foregoing description should be considered as merely illustrative of the principles of the present invention, and not in limitation thereof. Hence, the scope of the invention is only restricted by the appended patent claims.

1. A MEMS, microelectromechanical systems, resonator comprising:
an in-phase resonating element and an out-of-phase resonating element positioned adjacently, wherein
the in-phase resonating element and the out-of-phase resonating element are mechanically connected but galvanically isolated.

2. The MEMS resonator of claim 1, wherein respective bottom electrodes of the in-phase resonating element and the out-of-phase resonating element are galvanically isolated.

3. The MEMS resonator of claim 1, wherein the in-phase resonating element and the out-of-phase resonating element are galvanically isolated by a mechanically connecting but electrically resistive region.

4. The MEMS resonator of claim 1, wherein both the in-phase resonating element and the out-of-phase resonating element have an ultra-heavily doped, UHD, bottom electrode of N-type.

5. The MEMS resonator of claim 1, wherein the in-phase resonating element and the out-of-phase resonating element are mechanically connected but galvanically isolated by a substantially undoped silicon region.

6. The MEMS resonator of claim 1, wherein the in-phase resonating element and the out-of-phase resonating element are UHD doped with N-and P-type doping in an alternating fashion so that the in-phase resonating element has a UHD doped bottom electrode of one type and the out-of-phase resonating element has a UHD doped bottom electrode of the other type.

7. The MEMS resonator of claim 1, wherein the in-phase resonating element and the out-of-phase resonating element are mechanically connected but galvanically isolated by a depletion region of a PN junction.

8. The MEMS resonator of claim 1, comprising a reduced or increased width or length of the in-phase resonating element or the out-of-phase resonating element to counterbalance a drive level dependency, DLD, effect.

9. The MEMS resonator of claim 1, wherein the in-phase resonating element and the out-of-phase resonating element are mechanically connected but galvanically isolated by a silicon dioxide region.

10. The MEMS resonator of claim 1, wherein the in-phase resonating element and the out-of-phase resonating element form an overtone resonator.

11. The MEMS resonator of claim 1, wherein a top electrode of the in-phase resonating element is galvanically connected to a bottom electrode of the out-of-phase resonating element.

12. The MEMS resonator of claim 1, wherein a top electrode of the in-phase resonating element is galvanically connected to a bottom electrode of the out-of-phase resonating element via a hole extending through an intermediate piezoelectric layer outside or inside of a region of the resonating element(s).

13. The MEMS resonator of any claim 1, wherein the in-phase resonating element and the out-of-phase resonating element are mechanically connected throughout respective side(s) of the resonating elements.

14. The MEMS resonator of claim 1, wherein the in-phase resonating element and the out-of-phase resonating element are mechanically connected via connection elements in a piezoelectric layer but mechanically released in the region of bottom electrodes of the in-phase and out-of-phase resonating elements.

15. The MEMS resonator of claim 1, wherein the resonating element(s) have a material stack comprising both a layer doped with P-type doping and a layer doped with N-type doping beneath a piezoelectric layer or separated by a piezoelectric layer.

16. The MEMS resonator of claim 1, wherein the in-phase resonating element and the out-of-phase resonating element are of the type stacked beam resonator where a plurality of adjacent resonating beams are connected with connection elements.

17. The MEMS resonator of claim 1, comprising a plurality of resonating elements, comprising a resonating element configured to resonate in an in-phase length-extensional, LE, resonance mode and another resonating element configured to resonate in a square-extensional, SE, resonance mode.

18. The MEMS resonator of claim 2, wherein the in-phase resonating element and the out-of-phase resonating element are galvanically isolated by a mechanically connecting but electrically resistive region.

19. The MEMS resonator of claim 2, wherein both the in-phase resonating element and the out-of-phase resonating element have an ultra-heavily doped, UHD, bottom electrode of N-type.

20. The MEMS resonator of claim 3, wherein both the in-phase resonating element and the out-of-phase resonating element have an ultra-heavily doped, UHD, bottom electrode of N-type.
